(19) United States
(12) Patent Application Publication
(10) Pub. No.: US 2025/0359361 A1
(43) Pub. Date: Nov. 20, 2025

(54) IMAGE SENSOR AND METHOD OF FABRICATING THEREOF

(71) Applicant: Taiwan Semiconductor Manufacturing Company, Ltd., Hsinchu (TW)

(72) Inventors: Ming-Hsien YANG, Taichung City (TW); Kun-Hui LIN, Tainan City (TW); Chun-Hao CHOU, Tainan City (TW); Kuo-Cheng LEE, Tainan City (TW)

(21) Appl. No.: 19/285,973

(22) Filed: Jul. 30, 2025

Related U.S. Application Data
(63) Continuation of application No. 18/405,919, filed on Jan. 5, 2024.
(60) Provisional application No. 63/519,335, filed on Aug. 14, 2023.

(51) Int. Cl. H10F 39/18; H10F 39/00

(52) U.S. Cl. CPC H10F 39/18; H10F 39/014; H10F 39/8053; H10F 39/8063; H10F 39/807

(57) ABSTRACT

A semiconductor device according to the present disclosure includes a semiconductor layer, a plurality of metal isolation features disposed in the semiconductor layer, wherein certain of the metal isolation features extend through the substrate to provide for full isolation between adjacent photodetectors and certain of the metal isolation features extend partially through the semiconductor layer to provide partially isolation between adjacent photodetectors.

### PRIORITY DATA

This application is a continuation of U.S. patent application Ser. No. 18/405,919, filed Jan. 5, 2024, which is a non-provisional application of U.S. Provisional Patent Application Ser. No. 63/519,335, filed Aug. 14, 2023, which are each herein incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Image sensors, such as complementary metal-oxide-semiconductor (CMOS) image sensors (CIS), are commonly found in modern-day consumer electronics. As image sensors shrink in size to keep up with the ever-increasing pixel resolution requirements, some existing image sensor structures may not provide sufficient performance when receiving unbalanced light to the pixels. Therefore, while existing CIS are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A is a top view of an embodiment of a layout of a CIS device having a plurality of color filter pixels, according to aspects of the present disclosure.

FIG. 1B is a perspective view of an embodiment of a layout of a CIS device having a plurality of pixels, according to aspects of the present disclosure.

FIG. 2 is a top view of an embodiment of another layout of a CIS device having a plurality of color filter pixels, according to aspects of the present disclosure.

FIG. 3 is a top view of an embodiment of another layout of a CIS device having a plurality of color filter pixels, according to aspects of the present disclosure.

FIG. 4 is a cross-sectional view of an embodiment of an image sensor having a plurality of dual photodetectors (DPD), according to aspects of the present disclosure.

FIGS. 5A and 5B illustrate a top view and a cross-sectional view respectively of an embodiment of an image sensor having a plurality of dual photodetectors (DPD) and illustrating a current flow, according to aspects of the present disclosure.

FIG. 5C illustrates a cross-sectional view of an embodiment of an image sensor having a plurality of dual photodetectors (DPD) having an offset component and illustrating a current flow, according to aspects of the present disclosure.

FIGS. 6A and 6B illustrate a top view and a cross-sectional view respectively of an embodiment of an image sensor having a plurality of quad photodetectors (QPD) and illustrating a current flow, according to aspects of the present disclosure.

FIG. 7 illustrates a block diagram of an embodiment of a CIS device having a lateral field charge modulator, according to aspects of the present disclosure.

FIG. 8 illustrates an embodiment of a wave diagram corresponding to the device of FIG. 7, according to aspects of the present disclosure.

FIG. 9A is a top view of another layout of an embodiment of a CIS device having a plurality of color filter pixels, according to aspects of the present disclosure.

FIG. 9B illustrates a block diagram illustrates a corresponding array of the CIS device of FIG. 9A having a lateral field charge modulator, according to aspects of the present disclosure.

FIGS. 9C and 9D illustrate cross-sectional views of an embodiment of the CIS device having a lateral field charge modulator, according to aspects of the present disclosure.

FIGS. 10A, 10B, 10C, and 10D are illustrative of examples of implementations of aspects of features of the CIS device of FIGS. 9A, 9B, 9C, and/or 9D, according to aspects of the present disclosure.

FIG. 11 is a flow chart of an embodiment of a method of forming a CIS device according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +1-15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

CIS devices may be implemented by a substrate or stacking substrates (e.g., semiconductor wafers) with backside illumination (BSI) configuration process. In some implementations, the CIS is a color sensor and uses color filters in a 1 color (1C), 4 color (4C), and 4C quadratic photo detector (QPD) configuration. The present disclosure provides an image sensor that includes photodetectors (or photodiodes), which are also referred to as channels, provided in a semiconductor layer and microlenses arranged over the photodetectors such that light passes through microlenses and is directed to the photodetectors. The photodetectors are separated from one another by a plurality of isolation features, in some implementations including a composite of grids with deep trench isolation features (e.g., backside deep trench isolation) that extend partially or completely through the semiconductor layer. In an embodiment, the isolation features may include a metal layer and a dielectric liner layer.

CIS may face a challenge in capturing light/radiation and processing the receipt of said light due to an imbalance from one photodetector to another. In particular, each photodetector may experience receiving unbalanced light (e.g., a different intensity or amount) in comparison with its neighboring photodetector due to manufacturing overlay constraints and/or incident light's chief ray angle. The overlay constraints give rise to the alignment challenges between the microlens, composite metal grid, and the backside deep trench isolation of the metal isolation features. In an embodiment, at an array edge, different channels may have different neighboring pixel color filter (CF) n-value, which makes incident light and final quantum efficiency (QE) differences in same CF pixels. In an embodiment, at the center and/or edge of an array, microlens to backside deep trench isolation overlay shift makes incident light not on backside deep trench isolation center, which can cause scattered light and final QE difference even within in same color filter pixels (e.g., within a quadratic photo detector pixel). In some instances of the embodiments discussed above, receiving unbalanced light may cause the photodetectors to be incapable of reaching full well capacity (FWC) in sufficient time. Thus, it is desired increase the response time of the sensor while compensating for these challenges.

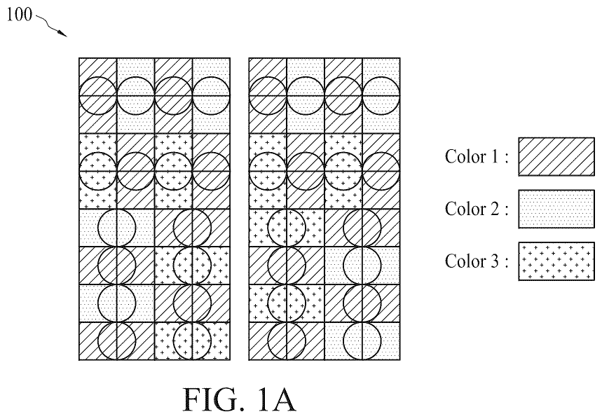

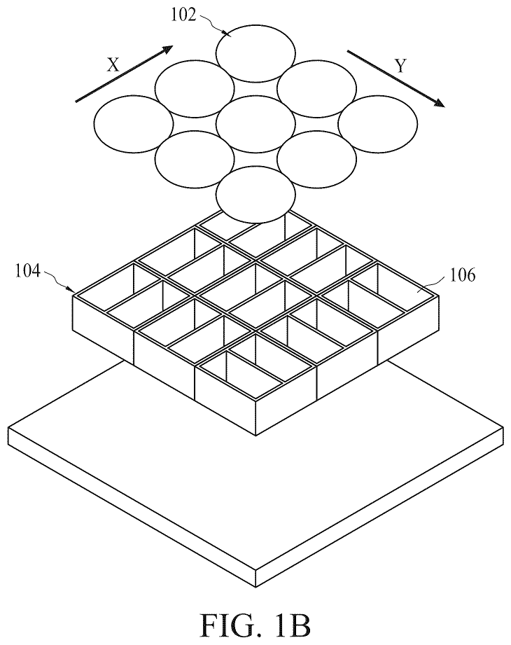

Various aspects of the present disclosure are described in more detail with reference to the figures. Referring first to FIGS. 1A, 2, and 3, illustrated are three different population diversity based local refinement strategies implementing layouts of an array of dual photodetectors illustrated as CIS 100, CIS 200, and CIS 300, respectively. In particular, FIGS. 1A, 2, and 3 each illustrate a top view of an array of pixels.

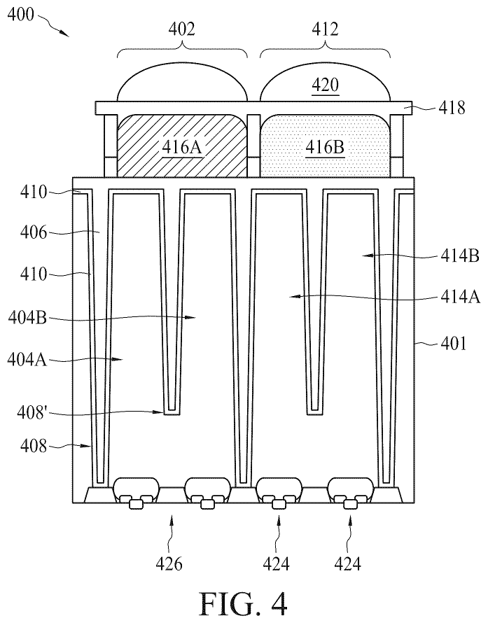

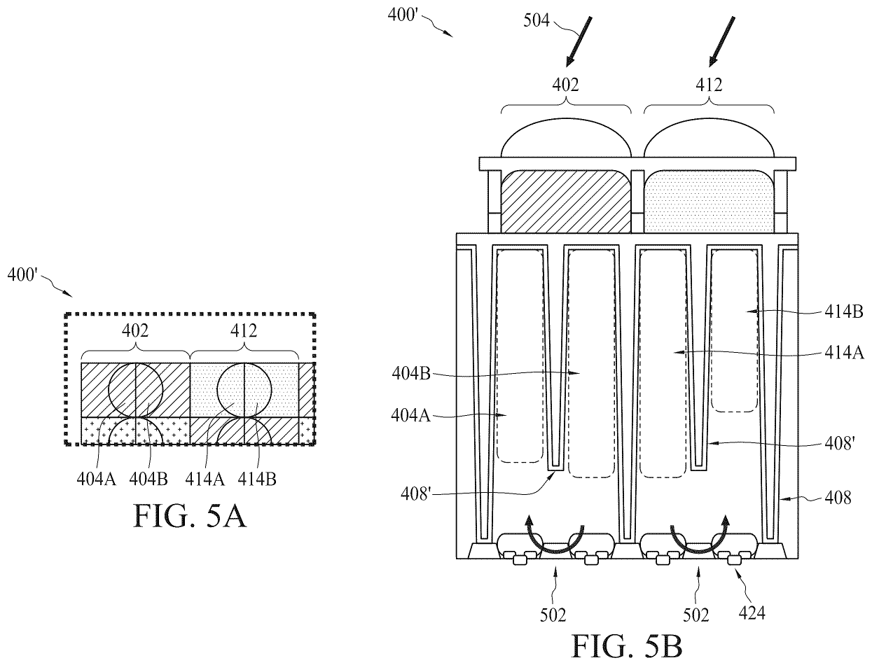

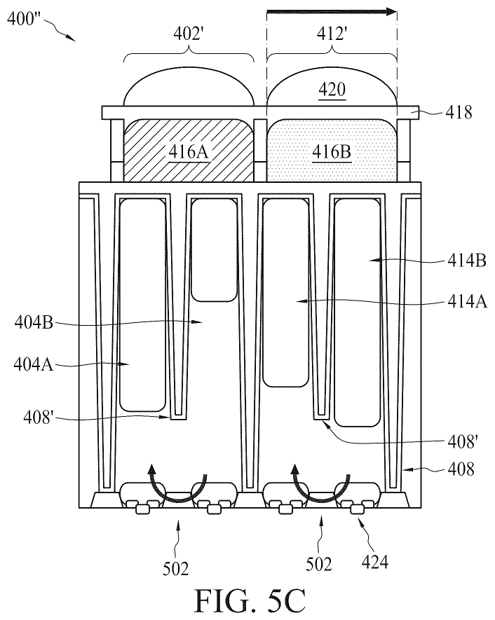

In FIG. 1A, CIS 100 is illustrative of a first pixel architecture. The CIS 100 has an array of color filters, which have overlying microlens (also in an array). Under the color filters are an array of photodetectors. In CIS 100, the photodetectors are configured as dual photodetectors (DPD). Each DPD is composed of two photodetectors of equal size. The two photodetectors of the DPD are each associated with a given color filter. That is, between a first DPD (associated with a first color filter) and an adjacent DPD (associated with a second color filter) a metal isolation feature including a metal grid and deep trench isolation are provided to provide complete isolation. Within a DPD, the two photodetectors, or channels, are not fully isolated from one another. Rather between the two photodetectors, a trench of the deep trench isolation, extends only partially between the channels as discussed below. Each of the two photodetectors of the DPD are associated with the same color filter. In other words, between the array of DPD, a full isolation is provided, for example, between a DPD of a first color and a DPD of a second color while a partial isolation is provided within a DPD. Further discussion of the partial isolation is described below including with reference to FIGS. 4 and 5.

CIS 100 includes pixels of a first color (e.g., green), a second color (e.g., red), and a third color (e.g., blue). The DPD of CIS on the left side of the array are oriented at a direction having a 90-degree angle in comparison of the DPD in the top portion to the bottom portion of the array portion. The DPD of CIS on the right side of the array are oriented at a 90-degree angle in comparison from the top portion to the bottom portion. In an embodiment, the top portion is oriented horizontally (e.g., a trench providing partial isolation between the first channel and the second channel extends horizontally on the page) and the bottom portion oriented vertically (e.g., a trench providing partial isolation between the first channel and the second channel extends vertically on the page). That is, one micro-lens is placed over two photodiodes (e.g., two and only two photodiodes). And in some implementations, those two photodiodes can share electrical charges as discussed in FIGS. 4, 5A, and 5B.

As in many implementations of the CIS 100, a radiation or light source can come from all directions (e.g., 3 dimensional (3D) and 0 to 180 degree incident angle of light), the configuration of the DPD provides for a benefit to capturing the incident light. In particular, in some implementations, in fabrication there may be an offset or shift between the micro-lens (illustrated as a circle) and the underlying photodiodes. This is illustrated in FIG. 1B. In some implementations, a shift or offset may also be present between the isolation (see, e.g., isolation 408 of FIGS. 4, 5A, 5B) and the micro-lens. The fabrication tolerances of the offset or shift between the lens and the photodiode/isolation may be compensated by the layout of FIG. 1A. In particular, an offset between the microlens and the photodiode/isolation can occur in an x-direction (left to right and vice versa in FIG. 1A, see also FIG. 1B) and also can occur in a y-direction (up and down and vice versa in FIG. 1A, see also FIG. B). This offset can be addressed by CIS 100 as it provides a combination of DPDs oriented vertically and horizontally. In other words, some DPDs are oriented with the photodetectors sharing an interface oriented in the x-direction such as the first two rows of CIS 100, and some DPDs are oriented with the photodetectors sharing an interface oriented in the y-direction such as the third and fourth rows of the CIS 100. The combination of orientations allows the CIS 100 to better compensate for offset between the microlens and the photodiode/isolation in both the x-direction and the y-direction. In some implementations, the configuration of the CIS 100 in terms of x-direction and y-direction interfaces between photodiodes under a microlens (i.e., which orientation the DPD is configured) is determined for the array based on computer simulation with an input factor of the incident light angle. It is noted that the interface is provided by a trench isolation structure that allows for transfer of photoelectric charge from one side to another side (e.g., isolation trench 408′ discussed below).

This offset direction is illustrated in a perspective view in FIG. 1B, which illustrates lens 102 over DPD 104 and DPD 106. The DPD 104 have two photodetectors or channels with an interface extending the x-direction; and the DPD 106 have two photodetectors or channels with an interface extending in the y-direction. Thus, as the lens are offset in the x-direction and/or the y-direction—or both directions—there are DPD that can compensate for the offset by sharing photoelectric charges over the interfaces from one photodetector to another.

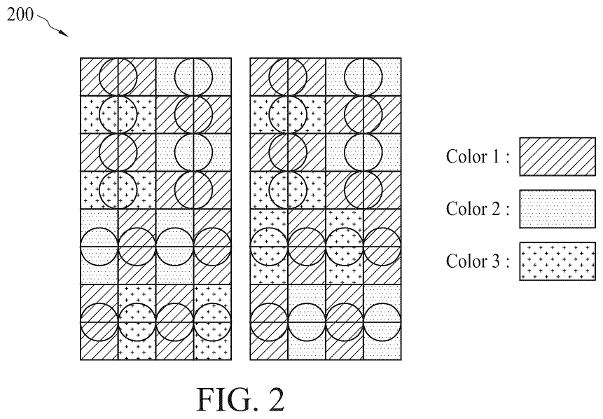

FIG. 2 shares several features in common with the CIS 100 of FIG. 1A, providing a different array configuration of DPD. In FIG. 2, CIS 200 is illustrative of a second pixel architecture. The CIS 200 has an array of color filters and lens. And the CIS 200 includes a dual photodetectors (DPD) below the color filters. Each DPD is composed of two photodetectors of equal size as discussed above. And again each of the two photodetectors or channels of the DPD are associated with the same color filter pixel. CIS 200 includes color filters of a first color (e.g., green), a second color (e.g., red), and a third color (e.g., blue). The DPD of CIS on the left side of the array are oriented at a 90-degree angle in comparison from the top portion to the bottom portion. The DPD of CIS on the right side of the array are oriented at a 90-degree angle in comparison from the top portion to the bottom portion (e.g., the interface between photodetectors is oriented in a perpendicular direction). Here the top portion is oriented vertically and the bottom portion oriented horizontally.

Like discussed with respect to the CIS 100, the CIS 200 may provide an advantage in addressing an offset between the photodiode (and the isolation surrounding the photodiode) and the lens. By implementing DPD in the CIS 200 where some DPD are oriented with an interface between the photodiodes (under a given lens) being oriented in a y-direction and some DPD are oriented with an interface between the photodiodes (under a given lens) being oriented in the x-direction, each direction is compensated for.

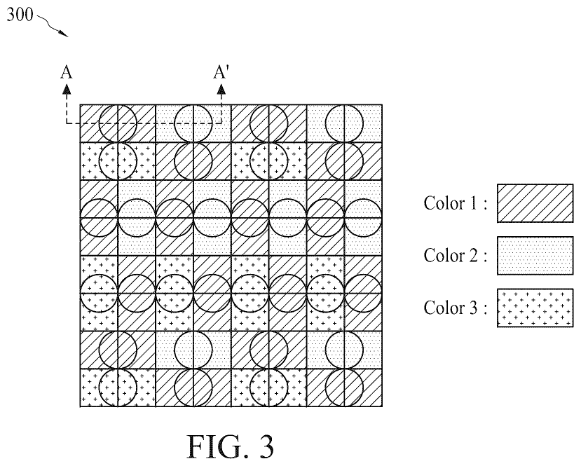

FIG. 3 shares several features in common with the CIS 100 of FIG. 1A, providing a different array configuration of DPD. In FIG. 3, CIS 300 is illustrative of a third pixel architecture. The CIS 300 has an array of color filters and lens. And the CIS 300 has an array of dual photodetectors (DPD) below the color filters. Each DPD is composed of two photodetectors of equal size and each of the two photodetectors for the same color filter pixel. CIS 300 includes pixels of a first color (e.g., green), a second color (e.g., red), and a third color (e.g., blue). The DPD of CIS 300 includes a top two rows of pixels oriented vertically; and the next two rows (below the top two rows) oriented horizontally; and the following two rows (below the middle two rows) again oriented vertically. In some implementations, where an incident light is from all directions (e.g., 360 degree surrounding light), CIS 300 may have advantages in sensing effectiveness. Again like discussed with respect to the CIS 100, the CIS 300 may provide an advantage in addressing an offset between the photodiode (and the isolation surrounding the photodiode) and the lens. By implementing DPD in the CIS 200 where some DPD are oriented with an interface between the photodiodes under a given photolens being oriented in a y-direction and some DPD are oriented with an interface bewteen the photodiodes under a given photolens being oriented in the x-direction, each direction is compensated for.

The arrays of CIS 100, CIS 200, and CIS 300 may be repeated any number of times across the respective devices. In some implementations, the CIS 100, CIS 200, CIS 300 are well suited to machine vision applications. A drawback of one or more of the layouts may be the resolution in a selected direction. For example, the vertical resolution may be only half of the horizontal resolution or vice versa depending on the orientation of the DPD. Compare top left quadrant of the section illustrated in FIG. 1A, which has greater resolution in a horizontal direction than vertical direction and bottom left quadrant of the section illustrated in FIG. 1A, which has greater resolution in a vertical direction than horizontal direction.

The arrays of CIS 100, CIS 200, and CIS 300 are illustrated to provide three different colors of filters. In some implementations, these colors are blue, green and red. However, other implementations are possible for these and all color filters of the present disclosure. In some implementations, the color filters may include red, blue, green, yellow, cyan, white, and/or other suitable color filter. The arrays of CIS 100, CIS 200, and CIS 300 may be 1 color (C), 4C, 9C, 16C, 32C, 36C, or the like. In some instances, one or more of the layouts of CIS 100, CIS 200, and CIS 300 provide for an improved population diversity based local refinement (PDLR) to enhance the high dynamic range (HDR) of the sensors.

In each of the layouts the configuration of DPD and the orientation of the interface between the photodetectors of each DPD (e.g., the two photodiodes under the lens) is selected to extend in a given direction—either x-direction or y-direction. The x-direction interface allows, as discussed with respect to FIG. 4, the sharing of electrical charge through the interface oriented in an x-direction. Thus, should an offset of the lens to the photodetectors occur, the DPD is able to better capture light by for example sharing electrical charge generated in a top diode to bottom diode through the x-oriented interface. The y-direction interface allows, as discussed with respect to FIG. 4, the sharing of electrical chart via the interface oriented in an y-direction. Thus, should an offset of the lens to the photodiodes occur the DPD is able to better capture light by for example sharing electrical charge generated in a right diode to left diode through the y-oriented interface.

Referring now to FIG. 4, illustrated is a cross-sectional view of an image sensor 400 including two DPD 402 for a given color filter of an array of pixels, such as implemented in the CIS 100, CIS 200, and/or CIS 300, discussed above. In particular, the cross-section A-A′ of the CIS 300 of FIG. 3 corresponds to the cross-sectional view of CIS 400 of FIG. 4.

The CIS 400 includes a substrate 401. The substrate 401 is a semiconductor substrate. The substrate 401 may be a bulk silicon (Si) substrate. Alternatively, substrate 401 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. In some implementations, substrate 401 includes one or more group III-V materials, one or more group II-VI materials, or combinations thereof. In still some instances, substrate 401 is a semiconductor-on-insulator substrate, such as a silicon-on-insulator (SOI) substrate, a silicon germanium-on-insulator (SGOI) substrate, or a germanium-on-insulator (GeOI) substrate. In still some embodiments, the substrate 401 may be diamond substrate or a sapphire substrate.

To form CIS 400, photosensitive regions are formed in substrate 401 to form photodetectors. To that effect, substrate 401 can include various doped regions (not shown), such as p-type doped regions, n-type doped regions, or combinations thereof. In one embodiment, the substrate 401 may include p-type dopants, such as boron (B), boron difluoride (BF₂), or other p-type dopants as well as n-type dopants, such as phosphorus (P), arsenic (As), or other n-type dopants. The implants may form channels (e.g., 404A/404B, 414A/414B), which may also be referred to photodetectors or photodiodes, when defined by the metal isolation feature (e.g., 406,408,408′) discussed below.

The substrate 401 has undergone processing to form features on a first, referred to as front, side. In some implementations, the features formed on the substrate 401 include a plurality of transistors 424 that are configured to process signals of the CIS 400. Each of the transistors 424 includes a source, a drain, a channel region disposed between the source and drain, and a gate structure over the channel region. It is noted that the transistor 424 shown in FIG. 4 may represent transistor of different configurations. For example, the transistors 424 may be planar transistors, fin-type field effect transistors (FINFETs), multi-bridge-channel (MBC) transistors, gate-all-around (GAA) transistors, nanowire transistors, nanosheet transistors, transistors with nanostructures, or other multi-gate transistors where the gate structure engages more than one surfaces of the channel region. The transistor 424 may be a high-k metal gate device for example providing a high-k dielectric as a gate dielectric and a metal gate electrode. The transistor 424 may alternatively be a transistor having a polysilicon gate. In an embodiment, the transistor 242 includes a source/drain region forming of epitaxially grown material on a recess within, or surface of, the substrate 401. In some implementations, the epitaxially grown material includes silicon germanium (SiGe). In an embodiment, the transistors 424 may be silicon-on-insulator (SOI) devices.

On the first side of the substrate 401, isolation features 426 are also formed. The isolation features 426 may also be referred to as shallow trench isolation (STI) features and may include silicon oxide, silicon nitride, silicon oxynitride, fluorine-doped silicate glass (FSG), a low-k dielectric, combinations thereof, and/or other suitable materials. The CIS 400 may further include additional layers such as an interlayer dielectric (ILD) disposed over the surface and the transistors 424. The ILD may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. One or more multi-layer conductive interconnect features (not shown) may be formed over and connected to the transistors 424 and extend through the ILD to form a multi-layer interconnect (MLI), such as discussed in further detail below.

In some implementations, the CIS 400 is a backside illuminated sensor (BIS). In a further embodiment, the substrate 401 is flipped and then image sensor features discussed below are formed on the backside of the substrate 401 to form the BIS. The CIS 400 includes a first DPD 402 (left) associated with a first color filter 416. The DPD 402 includes a first photodetector or channel 404A and a second photodetector or channel 404B. The CIS 400 also includes a second DPD 412 (right) associated with a second color filter. The DPD 412 includes a first channel 414A and a second channel 414B.

An isolation structure defines the photodetector regions to form the pixels. The isolation structure includes a metal grid 406 and a backside deep trench isolation (BDTI) 408 to form a composite isolation grid between the channels. Each of the metal grid 406 and BDTI 408, which are contiguous include a liner layer illustrated as liner 410 (e.g., a dielectric liner). And may include a metal layer on the liner 410. The BDTI 408 extends between the first DPD 402 and the second DPD 412 providing full isolation. The BDTI 408 extends through the substrate 401 until the isolation 426, extending such that BDTI 408 interfaces the isolation region 426. The BDTI 408 also provides full isolation from DPD 402 and the adjacent channel (not shown) and full isolation from DPD 412 and the adjacent (not shown). The isolation structure also illustrates the trench isolation 408′, which extends between the first channel 404A and the second channel 404B of the DPD 402. The trench isolation 408′ does not provide full isolation between the channels 404A and 404B, rather the trench isolation 408′ terminates at a depth that is within the channel region.

A first color filter 416A is formed over the DPD 402; and a second color filter 416B is formed over the DPD 412. The first color filter 416A is associated with a different color than the second color filter 416B. For example, in an embodiment, the first color filter 416A is green and the second color filter 416B is red. An underlayer 418 is disposed over the filters 416A/416B. The underlayer 418 may be a dielectric film and in some implementations, may be formed by chemical vapor deposition (CVD). A first microlens 420 is formed over the first color filter 416A and a second microlens 420 is formed over the second color filter 416B. As stated above, directions such as over and under are exemplary only to illustrate relative position of components and may be reversed in orientation.

These features of the CIS 400 introduced above are now discussed in further detail. In some implementations, after forming the frontside devices (e.g., transistor 424 and isolation regions 426), the backside of the substrate 401 is patterned to form openings for the deep trench isolation features 408/408′. In some implementations, photolithography processes and etch processes are performed to pattern hard mask over the backside of the substrate 401. For example, a photoresist layer (not shown) is formed over a hard mask, exposed to a suitable photolithography radiation source, and developed to form a patterned photoresist layer. The substrate 401 is then anisotropically etched using the patterned hard mask and/or resist as an etch mask, thereby forming a plurality of trenches. In an embodiment, the trenches are formed by anisotropic etch may be a dry etch process that implements sulfur hexafluoride (SF₆), carbon tetrafluoride (CF₄), nitrogen trifluoride (NF₃), other fluorine-containing gas, oxygen (O₂), or a combinations thereof. As shown in FIG. 4, more than one deep trench may be formed—some extending to the isolation features 426 formed on the frontside of the substrate 401 as illustrated by BDTI 408 and some trenches terminating within the substrate 401 as illustrated by trenches 408′. These trenches may be formed in the same or different patterning and etch processes.

In an embodiment, a dielectric liner layer 410 is formed as part of the metal isolation feature including on the backside of the substrate 401 and the BDTI 408/408′. The dielectric liner layer 410 may be a multi-layer structure. Example compositions include high-k dielectric materials such as aluminum oxide, hafnium oxide, tantalum oxide and the like. The dielectric liner layer 410 may be deposited by atomic layer deposition (ALD), chemical vapor deposition (CVD), or other suitable process. In an implementation, the dielectric liner layer 410 also includes a silicon oxide layer. For example, in some embodiments, the dielectric liner layer 410 includes a high-k dielectric and a silicon oxide layer.

To form the isolation structure including the BDTI 408/408′ and metal grid 406, metal may be deposited over the substrate 401 backside and along etched trenches. The deposition may be performed using physical vapor deposition (PVD), chemical vapor deposition (CVD), or other suitable deposition processes. After the deposition of the metal, a chemical mechanical polishing (CMP) process may be performed. The BDTI 408 and 408′ may be formed of aluminum (Al), tungsten (W), ruthenium (Ru), cobalt (Co), copper (Cu), or other suitable materials. In one embodiment, the BDTI 408 and 408′ are formed of tungsten (W).

The BDTI 408, which extend to through the substrate 401 to the isolation regions 426 on a frontside of the substrate 401, provide fully isolation between regions (e.g., between pixels). The metal isolation feature (metal grid 406, BDTI 408) is formed in a grid-shape providing isolation at the edges of each pixel, such as the edges of each of the pixels (color filters) in CIS 100, CIS 200, and CIS 300 of FIGS. 1, 2, and 3, respectively. The trench isolation features 408′ of the isolation structure do not provide full isolation, rather it allows flow between adjacent channels. The trench isolation features 408′ provide a barrier between portions of two channels of a single pixel (e.g., between two photodetectors associated with a single color filter). For example, trench isolation features 408′ define a separation of portions of the two channels of DPD 402 and a separation of portions of the two channels of DPD 412. The trench isolation features 408′ define the vertical/horizontal line within the DPD in each of CIS 100, CIS 200, and CIS 300 of FIGS. 1, 2, and 3, respectively. That is, the trench isolation features 408 and 408′ define and isolate (in whole or in part) the photodetectors to provide the channels (e.g., 404, 414). The isolation features 408′ extend from a surface of the substrate but terminate—such that the isolation feature 408′ has a terminal end within the substrate. Thus, a distance of substrate is provided below that is capable of transferring charge.

The isolation feature including the grid 406 including the trench isolation 408/408′ may include a metal portion and a dielectric portion. In some implementations, the dielectric portion is provided by the liner layer 410. Like the grid 406 region, the DTI features 408/408′ may be configured in a grid (e.g., defining the grid of photodetectors). In an embodiment, the grid 406 and/or DTI features 408/408′ include tungsten and titanium nitride (TiN). Other materials include tungsten, a pure metal, a compound alloy, TiN, ceramic materials, and/or other suitable compositions. In an embodiment, the grid 406 and/or DTI features 408/408′ may include a dielectric portion comprising Al₂O₃, SiO₂, or other suitable dielectric materials in addition to or in lieu of the liner layer.

In some implementations, the grid 406 and/or DTI features 408/408′ include a first dielectric portion including SiO₂, other suitable dielectric materials, or ceramic materials, where the materials have an index of refraction n between approximately 1 and approximately 1.48. In some implementations, the grid 406 and/or DTI features 408/408′ include a second dielectric portion (in addition to the first dielectric portion) comprising SiO₂, other suitable dielectric materials, or ceramic materials, where the materials have an index of refraction n between approximately 1 and approximately 1.48. In a further embodiment, the second portion of the grid 406 and/or DTI features 408/408′ include dielectric materials comprising a filler providing an index of refraction n without limit. In some implementations, the grid 406 and/or DTI features 408/408′ include a first dielectric portion and a second dielectric portion where the first dielectric portion has an index of refraction equal to or less than that of the second dielectric portion.

The color filters 416A, 416B are formed over the backside of the substrate 401. The color filters 416A, 416B may be formed of a polymeric material or a resin that includes color pigments. The color filter layer is formed of a material that allows for the transmission of radiation (e.g., light) having a specific range of wavelength, while blocking light of wavelengths outside of the specified range. The underlayer 418 is formed over the color filters 416A, 416B. Example compositions include an organic or polymeric material that has a high transmittance rate for visible light. This allows light to pass through the underlayer 418 with very little distortion so that it can be detected by the photodetectors of columns 404/414. The underlayer 418 may be formed by a spin-on coating method which provides for a uniform and even layer.

Microlens (or simiply lens) features 420 are formed over the underlayer 418 and the filters 416A, 416B, respectively. The microlens 420 may be formed of any material that may be patterned and formed into lenses, such as a high transmittance acrylic polymer. In an embodiment, a microlens layer may be formed using a material in a liquid state and spin-on techniques. Other methods, such as CVD, PVD, or the like, may also be used. The planar material for the microlens layer may be patterned using a photolithography and etch technique to pattern the planar material in an array corresponding to the array of photodetectors. The deposited material may then be reflowed to form an appropriate curved surface for the microlens 420. The microlens 420 may be cured using an ultraviolet (UV) treatment. For a DPD configuration, such as DPD 402 and DPD 412, a single lens extends over each of the channels or photodetector 404A and 404B of DPD 402; and a single lens extends over each of the channel or photodetector 414A and 414B of DPD 412.

It is noted that while FIG. 4 illustrates a backside illuminated sensor (BSI), in other embodiments, the present disclosure is also applicable to a frontside illuminated sensor. In an embodiment, various combinations of SOC and ASIC substrates (e.g., wafers) may be used to fabricate the image sensors of FIG. 4 and the other embodiments of the disclosure. In a further embodiment, the CIS is a FSI device and includes a single wafer image sensor. In an embodiment, the CIS is a BSI device and is based on a plurality of combinations of SOC and ASIC wafers.

Referring now to FIGS. 5A and 5B, illustrated is the CIS 400′ substantially similar to the CIS 400 discussed above with reference to FIG. 4. The CIS 400′ includes a plurality of a dual photodetector (DPD) devices, illustrated as 402 and 412, which form a portion of the array of CIS 400′. A BDTI 408 extends through the substrate 401 between pixels as discussed above. And a backside trench isolation 408′ provides partial isolation by extending partially through the substrate 401 between photodetectors within a given pixel (e.g., adjacent channels of a single DPD associated with one color filter). In FIG. 5B, incident light 504 is illustrated. The incident light 504 passes through the lens 420 and the color filter 416A/416B to the photodetectors.

FIG. 5B illustrates a generated current flow 502 (e.g., photoelectric current) extending from a first photodetector or channel 402B of the DPD 402 to a second photodetector or channel 402A of the DPD 402. And FIG. 5B also illustrates a separate current flow 502 extending from a first photodetector or channel 414A of the DPD 412 to a second photodetector or channel 414B of the DPD 412. In some implementations, the current flows 502 of DPD 402 serves to balance the electrical charge between the channel 402A and the channel 402B. In the DPD 412, the current flow 502 separately serves to balance the electrical charge of its channels 414A and 414B. The electrical charge induced in each of the channels or photodetectors 402A, 402B, 402C, 402D are illustrated by the dashed outlines of FIG. 5B.

In an embodiment, the current flow 502 from the channel 402B to the channel 402A mitigates the issue of an unbalanced receipt of light within the DPD 402. For example, in the embodiment of DPD 402, which may include a color filter 416 of a first color (e.g., green), channel or photodetector 402B has a greater photo-electric current than channel or photodetector 402A due to, for example, an imbalance in received light. See FIG. 5C. When the level of stored electric charges exceeds the trench isolation 408′ (which provides only partial isolation), an overflow current 502 from channel 402B to channel 402A will be induced. Therefore, in some implementations, the electric charge storage of channel 402A to channel 402B can be balanced to reach full well capacity (FWC) more efficiently.

Similarly, in an embodiment, the photoelectric current flow 502 from the channel 414A to the channel 414B mitigates the issue of an unbalanced receipt of light within the DPD 412. In some implementations, the unbalanced receipt of light within the DPD 412 is due to overlay errors or received light as discussed above. For example, in some implementations, the grid 406, the BDTI 408/408′ and the channels 414A/414B are offset from desired alignment, in other words, there is an alignment shift in a given direction. FIG. 5C illustrates this offset in an x-direction. In some implementations, the unbalanced receipt of light within the DPD 412 is due to variations in the incident light to the DPD 412. For example, in the embodiment of DPD 412, which may include a color filter 416 of a second color (e.g., red), channel or photodetector 414A has a greater photo-electric current than channel or photodetector 414B due to, for example, an imbalance in received light. Similarly, when the level of stored electric charges exceeds the backside trench isolation 408′ (which provides partial isolation), an overflow current 502 from channel 414A to channel 414B will be induced. Therefore, in some implementations, the electric charge storage of channel 414A to channel 414B can be balanced to reach full well capacity (FWC) more efficiently.

Thus, in operation, in some implementation, the current flow 502 can provide for the photoelectric current to flow into its neighbor PD of the DPD to balance FWC prior to pixel binning. Binning is the process of combining adjacent pixels throughout an image by summing or averaging their values during or after a readout. As the FWC is reached more efficiently, the response time of the sensor is improved.

Illustrated in FIG. 5C is a CIS device, referred to as CIS 400″ that is substantially similar to the CIS 400′ discussed above with reference to FIGS. 5A and 5B. FIG. 5C is illustrative of an offset (here shown in the x-direction) of the lens 420 (and the color filter 416) with respect to the photodetectors 414. Due to the binning process as discussed above, the offset is able to be tolerated with minimizing performance impacts as the photoelectric current is able to be transferred from photodetector or channel 414B to channel or photodetector 414A, which receives less light due to the offset in the x-direction. In other examples the offset is alternatively or additionally in a perpendicular direction (e.g., into the page of FIG. 5C).

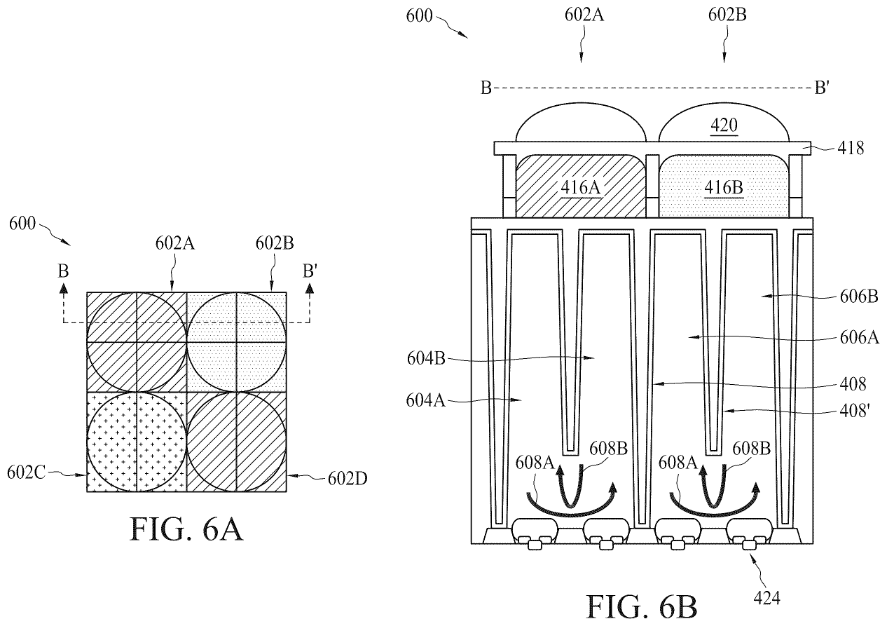

Referring now to FIGS. 6A and 6B, illustrated is a CIS 600. The CIS 600 includes a plurality of quadratic photo detectors (QPD) in an array. QPD 602A, 602B, 602C, and 602D are illustrated in top view of the CIS 600 in FIG. 6A. The QPD 602A is associated with a first color filter (e.g., green), QPD 602B is associated with a second color filter (e.g., red), QPD 602C is associated with a third color filter (e.g., blue) and QPD 602D is associated with the first color filter. However, other arrangements of the array are also possible. The portion illustrated in FIG. 6A is representative of a small section of an array of QPDs forming the CIS 600. Each QPD is composed of four photodetectors (or channels or cells) of equal quadrant size. Each of the four quadrants is associated with a single color filter.

Some of the features of the CIS 600 implementing QPD are substantially similar to the associated features implementing DPD discussed above with reference to FIG. 4 and the CIS 400 and similar reference numbers refer to similar features. FIG. 6B is illustrative of a cross-sectional view of the QPD 602A and the QPD 602B along B-B′. A BDTI 408 extends through the substrate 401 between QPD 602A and the QPD 602B. The BDTI 408 may fully isolate the QPD 602A from the QPD 602B. A trench isolation 408′ provides partial isolation between channels within QPD 602A (and within QPD 602B) by extending partially through the substrate 401; trench isolation 408′ extends between each of the four quadrants of photodetectors within a given QPD. It is noted the cross-sectional view of a given QPD (e.g., QPD 602A) along a cut perpendicular to the B-B′ cut (e.g., vertical in FIG. 6A) is substantially similar to as illustrated along cut B-B′ because the QPD 602A includes four equal quadrants.

FIG. 6B also illustrates a first current flow 608A extending from a first photodetector or channel 604A of the QPD 602A to a second photodetector or channel 604B of the QPD 602A. In other words, the first current flow 608A is in a horizontal direction along the page of FIG. 6A, or along the direction of the cross-sectional cut B-B′. Similarly, current flow 608A extends from a first photodetector or channel 606A of the QPD 602B to a second photodetector or channel 606B of the QPD 602B. In some implementations, the current flow 608A serves to balance the electrical charge of the channels 604A and 604B similar to as discussed above with reference to FIG. 5. And in some implementations, the separate current flow 608A serves to similarly balance the electrical charge of the channels 606A and 606B.

FIG. 6B also illustrates a second current flow 608B extending from the first photodetector or channel 604A and/or the second photodetector or channel 604B of the QPD 602A to other quadrants (other channels, in particular other two channels) of the QPD 602A. In particular, the current flow 608B is a current extending perpendicular to the cross-sectional cut B-B′ (e.g., into or out of the page of the figure) such that the charge is distributed to and/or from the other two channels (not shown in FIG. 6B) of the QPD 602A. Similarly, current flow 608B extends from the first photodetector or channel 606A and/or the second photodetector or channel 606B of the QPD 602B to other quadrants (other channels) of the QPD 602A. In some implementations, the current flows 608A and 608B within QPD 602A serves to balance the electrical charge of each of the four photodetectors or channels of the QPD 602A. In some implementations, the separate current flows 608A and 608B within QPD 602B serves to balance the electrical charge of each of the four photodetectors or channels of the QPD 602B. In other words, for a given channel (e.g., 604A) there are three other channels of the QPD that can provide a charge to/from the given channel. Again, in implementations, there is full isolation between the photodetectors or channels of QPD 602A and QPD 602B resulting in no current flow between the two QPDs.

In an embodiment, the current flows 608A/608B between the four (4) channels or photodetectors of the QPD 602A mitigates the issue of an unbalanced receipt of light within the QPD 602A. In some implementations, the unbalanced receipt of light within the QPD 602A is due to overlay errors as discussed above. And in some implementations, the unbalanced receipt of light within the QPD 602A is due to variations in the incident light. In an exemplary operation of the CIS 600, in the embodiment of QPD 602A, which may include a color filter 416 of a first color (e.g., green), channel or photodetector 604A has a greater photo-electric current than channel or photodetector 604B (and/or one or more of the other channel or photodetectors of the QPD 602A) due to, for example, an imbalance in received light. When the level of stored electric charges exceeds the trench isolation 408′ (which provides partial isolation), an overflow current 608A from channel 604A to channel 604B will be induced, and an overflow current 608B from channel 604A and/or channel 604B will be induced to one or both of the other two channels of the QPD 602A. Therefore, in some implementations, the electric charge storage of the channels or photodetectors of the QPD can be balanced to reach full well capacity (FWC) more efficiently.

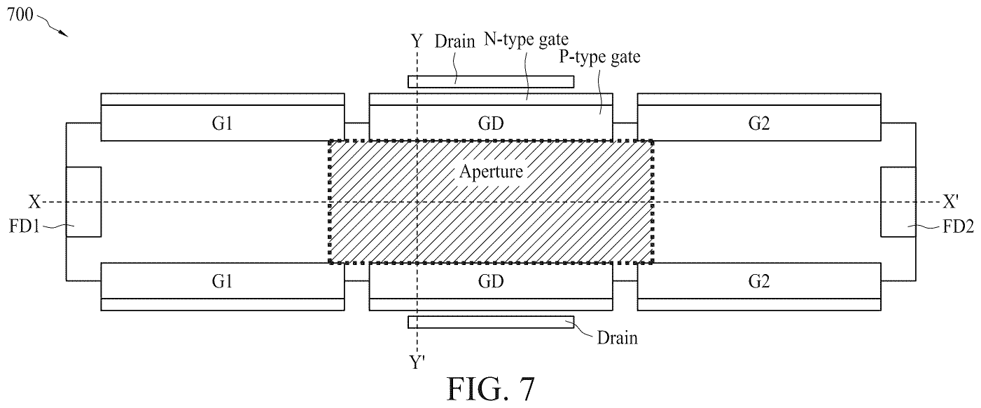

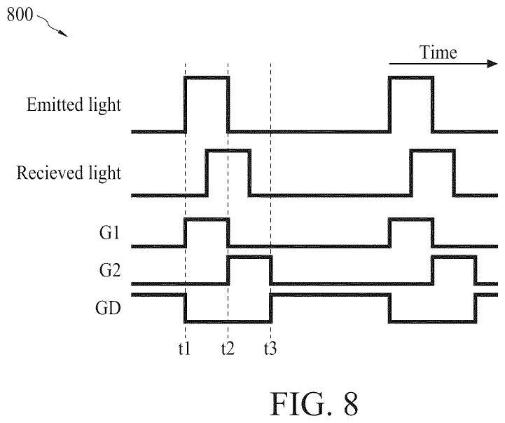

Referring now to FIGS. 7-8, the present disclosure discusses using lateral electrical field charge modulator(s) (LEFM) to an CIS. In some implementations, providing LEFM enhances the high dynamic range (HDR) of an CIS. The LEFM does not have a transfer gate in a signal path for output from the pixel, allows for high-speed charge modulation, and/or loss-less charge modulation.

FIG. 7 illustrates a top view of a device 700 including LEFM with a drain in which two sets of gates (G1 and G2) create a lateral electrical field. FD1 and FD2 provide for floating diffusions. FD1 and/or FD2 may be N-type implantations, P-type implantations (e.g., B), PN junction float capacitor, or a metal-insulator-metal (MIM) capacitor.

In an embodiment, the gates may not be used for transferring charge through the gate, but for controlling an electrical field in the x-x′ direction of FIG. 7 by changing a hole concentration of a pinned photodiode surface of the photodetector (aperture). In an embodiment, when G1 is high and G2 is low, photo electrons generated in the aperture region are transferred to FD1. That is, the direction of the electron flow in a pinned photodiode in controlled by the gates. FIG. 8 illustrates an exemplary operation of the device 700 in a wave diagram 800. At time t1, gate G1 is turned on and a lateral electric field is induced between two gates G1. And electric charges are stored at FD1. At time t2, gate G1 is turned off and gate G2 is turned on, and the electric charges at FD1 will then flow to FD2. At time t3, gate G1 and gate G2 are both turned off and gate GD is turned on, and the electric charges will flow to gate GD. Thus, under some embodiments, each channel (photodetector) in the same color filter pixel (e.g., red, blue, green) can reach full well capacity (FWC) more efficiently. And in some implementations, the output pixel value can reach a higher level, thereby enhancing HDR.

In some implementations, when the sensor experiences significant light exposure (e.g, >1,000,000 lux), G1, G2, GD turn on and off by an order of G1 then G2 then GD. In such an implementation, gates G1 and G2 serve to be a receiver of the signals (e.g., act as major signal receiver). And the gate GD in such an implementation may be the background noise receiver. In an embodiment, the gate GD is a dual control gate and performs the role of drain gate (e.g., drain out sunlight noise).

When the sensor experiences relatively low light exposure (e.g., dimming light, almost dark such as <100 lux), gates G1, G2, and GD turn on and off by an order of GD then G1 then G2. In such an implementation, the gate GD performs the role of the major signal receiver. And gates G1 and G2 are the background noise receivers of low light. The gate GD may be very sensitive to low light due to its dual control gate (more current signal) and G1 and G2 change their role from control gate to drain gate (drain out noise current).

Thus, it is appreciated by the present disclosure that the advantages of gate GD being a dual gate but gates G1 and G2 are individually single gates. This is because at higher light exposure, gate GD collects more background sunlight noise that is needed to drain out. And at low light exposure, gate GD, and its dual gate configuration, plays a role of higher sensitivity major signal collector. Thus, in some implementations of the device of FIG. 7, the layout includes of gate GD comprising a dual control gate and each of gates G1 and G2 being single control gate.

In some implementations, the device may be implemented with bipolar-gates. In an embodiment, illustrated in FIG. 7, a p-type gate and an n-type gate are formed for each of G1, G2, GD.

Additional details of the device 700 are provided and apply not only to the device 700 but the CIS 900 discussed below. In some implementations, the LEFM is applied to the photodetector layers, including as discussed above, to move the charge of the photodetector layers. As discussed above, in an embodiment G1, G2, and GD are control gates as discussed above. In some implementations, at a very high light (e.g., >1,000,000 lux), G1 & G2 provide for major signal detection and GD collects surrounding noise, such as ambient sunlight. At very low light (e.g., <100 lux), G1 & G2 may change functions with GD; and GD may provide major signal detection and G1 & G2 can provide for background noise reference detection.

The gate structures G1, G2, and GD may be NMOS or CMOS devices, and in an embodiment, each of G1, G2 and GD are disposed on an NMOS region of the substrate. In an embodiment, a p-type gates have width ratio range with n-type gates of 1:1 to 1000:1, G1 & G2 are substantially identical, and/or GD is omitted. In an embodiment, p-type gates have a length ratio range with n-type gates of 1:1 to 1000:1, G1 & G2 are substantially identical, and/or GD is omitted. In an embodiment, because the ambient direct sunlight collected by GD is a very strong signal, it needs a greater area of p-type gate for GD to be turned off controlled manner. In an embodiment, gate GD width and length can be the same or greater than that of G1 and G2. This may be provided because in operation the device in some implementations can easily control a steep slope of channel for charge signal providing faster to floating diffusion regions FD1 and FD2. In some implementations, the p-type gate and n-type gate illustrated in FIG. 7 form P-N junction to generate electric field to control the slope (e.g., providing a steep slope) of channel.

In an embodiment, gates G1, G2, GD each connect to a same drain. In other embodiments, one or more of gates G1, G2, and GD may connect to a different drain region. In an embodiment, a GD p-type gate and n-type gate have width and length ratio range with G1 & G2 p-type gate and n-type gate of 1:1 to 1000:1. In an embodiment, gates G1 and G2 are substantially the same size and shape but can be mirror configuration of one another (or in other implementations, may not mirror one another). That is, G1 and G2 can be opposite to each other without any horizontal shift. Alternatively, G1 and G2 can also be opposite to each other with a horizontal shift.

It is noted that gates G1, G2 and/or GD shown in FIG. 7 may represent transistor of different configurations. For example, the gates G1, G2 and/or GD may be planar transistors, fin-type field effect transistors (FINFETs), multi-bridge-channel (MBC) transistors, gate-all-around (GAA) transistors, nanowire transistors, nanosheet transistors, transistors with nanostructures, or other multi-gate transistors where the gate structure engages more than one surfaces of the channel region. The gates G1, G2 and/or GD may be a high-k metal gate device for example providing a high-k dielectric as a gate dielectric and a metal gate electrode. In an embodiment, gates G1, G2 and/or GD include a source/drain region formed of epitaxially grown material on a recess or surface of the substrate 401. In some implementations, the epitaxially grown material includes silicon germanium (SiGe).

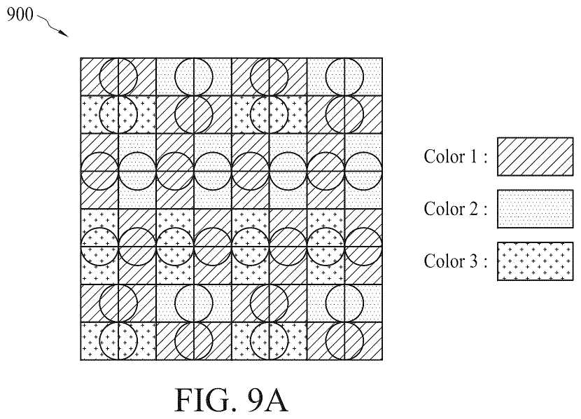

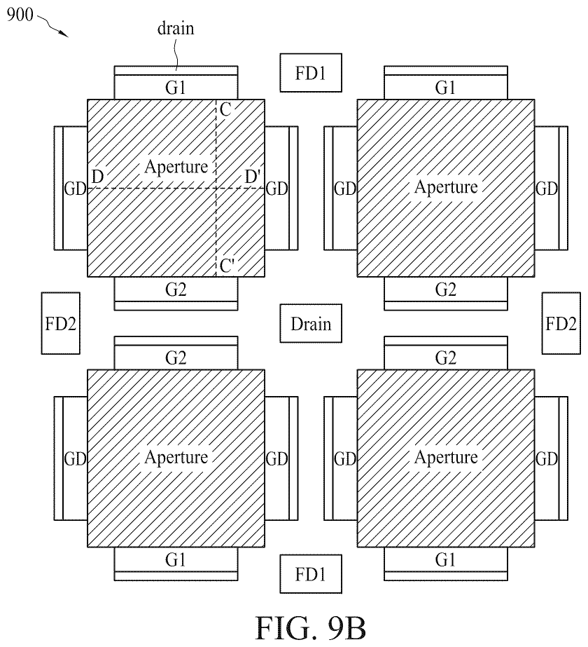

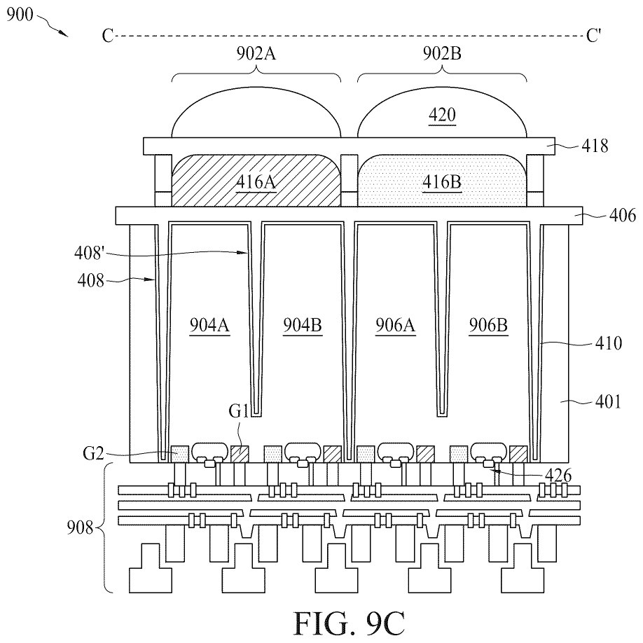

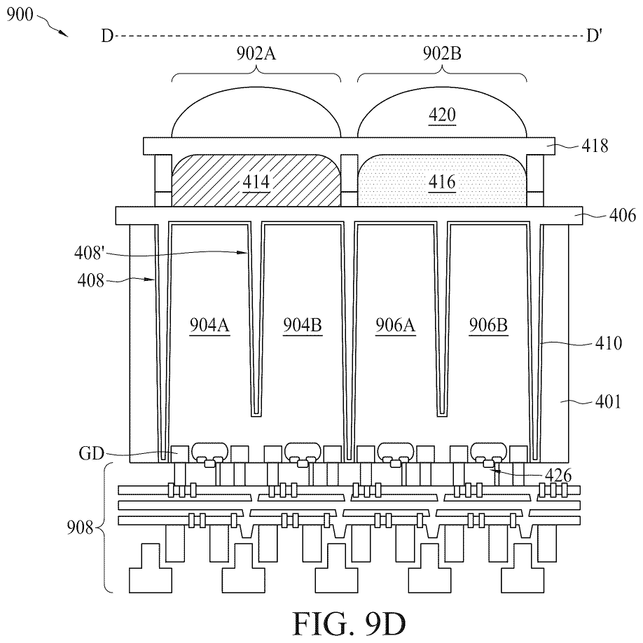

FIGS. 9A and 9B are illustrative of top views of a CIS 900 having an LEFM configuration. FIG. 9A is substantially similar to FIG. 3 discussed above and includes a plurality of pixels in an array, where each pixel including a color filter and DPD photodetector configuration. As discussed above, each DPD is composed of two photodetectors of equal size. And each of the two photodetectors are associated with the same color filter. CIS 900 includes pixels of a first color (e.g., green), a second color (e.g., red), and a third color (e.g., blue). However, the arrangement is not so limited. The array of CIS 900 includes a top two rows of pixels with DPD oriented vertically; and the next two rows (below the top two rows) with DPD oriented horizontally; and the following two rows (below the middle two rows) again with DPD oriented vertically. That is, the first two rows of the arrays of DPD provide for an overflow current flow from left—to—right or right—to—left (i.e., an x-direction) to balance the charge of each of the photodetectors or channels of the given DPD as discussed above with reference to FIG. 5. Similarly, the third and fourth rows of the arrays of DPD (from the top of FIG. 9A) provide for an overflow current flow from in the y-direction to balance the charge of each of the photodetectors or channels of the given DPD as discussed above with reference to FIG. 5.

FIG. 9B illustrates a top view of a block diagram of the CIS 900 having LEFM configuration. It is noted that each aperture corresponds to photodetector or column of a DPD (or QPD). The gates G1, G2, and/or GD may include n-type and/or p-type gates as discussed above. FIG. 9B is illustrative of a portion of the array of pixels and may be repeated any number of times across the CIS 900.

FIG. 9C illustrates a cross-sectional view of a portion of the CIS 900 along the direction of C-C′ in FIG. 9B. In particular, FIG. 9C is illustrative of a portion of the CIS 900 including two DPD 902A and 902B. In an embodiment, the DPD 902A and 902B are instead QPD substantially similar to as discussed above.

The CIS 900 shares many features with the CIS 400 discussed above and similar features are referred to using similar reference numbers. CIS 900 includes a substrate 401, which may be substantially similar to as discussed above. The first DPD 902A includes a first channel or photodetector 904A and a second channel or photodetector 904B. The second DPD 902B includes a first channel or photodetector 906A and a second channel or photodetector 906B. A metal isolation feature including composite metal grid 406 and BDTI 408/trench 408′ is formed between the channels. BDTI 408 extends between the first DPD 902A and the second DPD 902B providing full isolation. (And between adjacent pixels of a different color). The trench isolation 408′ extending between the first channel 904A and the second channel 904B of the DPD 902A does not provide full isolation but terminates within the channel region of the substrate 401. Similarly, the trench isolation 408′ extending between the first channel 906A and the second channel 906B of the DPD 902B does not provide full isolation but terminates within the channel region. Thus in both instances, the trench isolation 408′ allows for the flow of electrical charge from one channel to the adjacent channel including as discussed above with reference to FIGS. 5A-5C.

A first color filter 416A is formed over the DPD 902A; and a second color filter 416B is formed over the DPD 902B. The first color filter 416A is associated with a different color than the second color filter 416B. For example, in an embodiment, the first color filter 416A is green and the second color filter 416B is red. An underlayer 418 is disposed over the filters 416A/416B. A first microlens 420 is formed over the first color filter 416A and a second microlens 420 is formed over the second color filter 416B. Each of these features are discussed in further detail above, which apply equally to the embodiment of the CIS 900.

As also discussed above, frontside devices (e.g., transistor 424 and isolation regions) are formed on a first side of the substrate 401. In addition, in the embodiment of CIS 900, the LEFM configuration provides for gates G1, G2, and GD discussed above formed on the first side of the substrate 401. Referring to the example of FIG. 9C, a plurality of gates G1 and G2 are formed. In an embodiment, for the DPD 902A, two gates G1 and two gates G2 are formed. In an embodiment, for the DPD 902A, two gates G1 and two gates G2 are formed. In an embodiment, a first gate G1 is adjacent and spaced a distance from a gate G2 and the trench isolation 408′ providing incomplete isolation is disposed directly vertically above the distance between G1 and G2. In other words, one G1 and one G2 are associated with each channel of the DPD (e.g., 906A). In an embodiment, for the DPD 902A, two gates G1 and two gates G2 are formed. In an embodiment, for the DPD 902A, two gates G1 and two gates G2 are formed. In an embodiment, one of a first gate G1 and one of second gate G2 is adjacent the BDTI 408 providing isolation between the DPD 902A and an adjacent pixel. Above the devices 424, G1, G2 and the like on the first side of the substrate 401 may be a multiple layer interconnect (MLI) 908 that provides a plurality of conductive metal lines, vias, contacts, and input/output terminals. The MLI 908 electrically couples various devices (for example, transistors, resistors, capacitors, and/or inductors) and/or components (for example, gate electrodes and/or epitaxial source/drain features of p-type transistors and/or n-type transistors), such that the various devices and/or components can operate as specified by design requirements of the CIS 900. An MLI feature typically includes a combination of dielectric layers and electrically conductive layers (e.g., metal layers) configured to form various interconnect structures. The conductive layers are configured to form vertical interconnect features, such as device-level contacts and/or vias, and/or horizontal interconnect features, such as conductive lines. Vertical interconnect features typically connect horizontal interconnect features in different layers (or different planes) of MLI. Contact features extend to each of the G1, G2, and/or device 424. In some implementations, the contact features may include tungsten, ruthenium, cobalt, copper, aluminum, iridium, palladium, platinum, nickel, other low resistivity metal constituent, alloys thereof, or combinations thereof.

FIG. 9D illustrates a cross-sectional view of a portion of the CIS 900 along the direction of D-D′ in FIG. 9B. In particular, FIG. 9D is illustrative of a portion of the CIS 900 including two DPD (or QPD) 902A and 902B.

It is noted that the cross-sectional view of FIG. 9D includes many of the same features as that of FIG. 9C and the same reference numbers are applied to similar features. In some implementations, the DPD provided in FIG. 9C may be located at a different area of the array (e.g., different DPD) than the cross-sectional view provided in FIG. 9D. In particular, FIG. 9D is illustrative of a cross-sectional view through the gate GD of the LEFM configure device. Again as also discussed above, frontside devices (e.g., transistor 424 and isolation regions) are formed on a first side of the substrate 401. In addition, in the embodiment of CIS 900, the LEFM configuration provides for gates GD formed on the first side of the substrate 401. Referring to the example of FIG. 9D, a plurality of gates GD are formed. In an embodiment, for the DPD 902A, two gates GD are formed for the first channel 904A and two gates GD are formed for the second channel 904B. In an embodiment, a gate GD of channel 904A is adjacent and spaced a distance from a gate GD of channel 904B and the trench isolation 408′ providing incomplete isolation is disposed directly vertically above the distance between these GD. Above the devices 424, GD and the like on the first side of the substrate 401 may be the MLI 908 that provides a plurality of conductive metal lines, vias, contacts, and input/output terminals as discussed above. Contact features extend to each of the GD and/or device 424. In some implementations, the contact features may include tungsten, ruthenium, cobalt, copper, aluminum, iridium, palladium, platinum, nickel, other low resistivity metal constituent, alloys thereof, or combinations thereof.

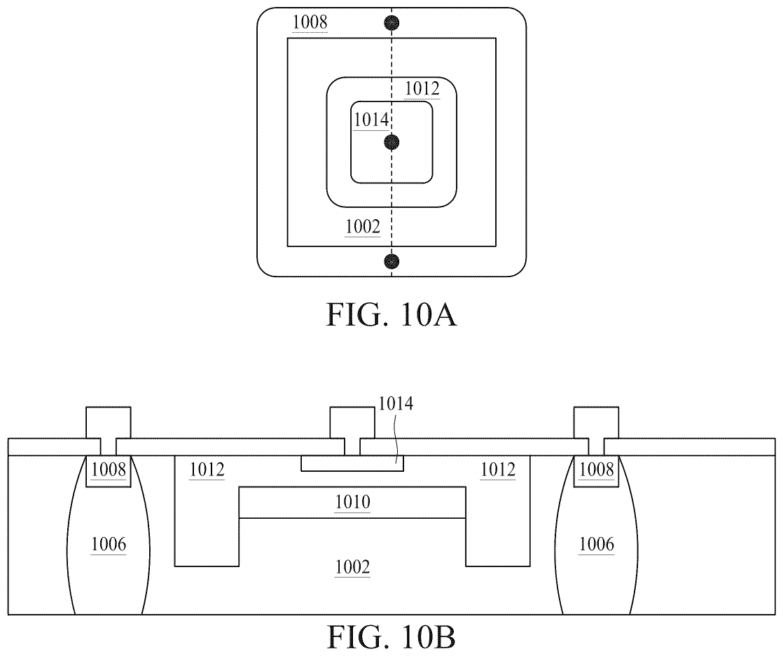

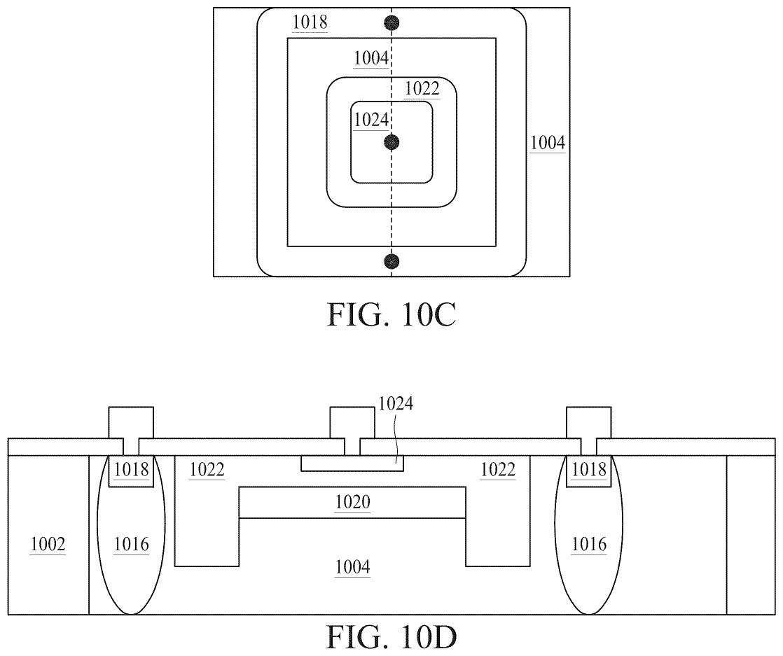

FIGS. 10A, 10B, 10C, and 10D are illustrative of example implementations of the gates G1, G2, and/or GD. FIGS. 10A and 10B illustrate exemplary gate(s) formed on a region of a P-doped substrate 1002. FIGS. 10C and 10D illustrate exemplary gate(s) formed on an n-well region 1004 of the substrate 1002. FIGS. 10A and 10B illustrate the N⁺P configuration of GD, G1, and/or G2. FIGS. 10C and 10D illustrate the PN⁺ configuration of GD, G1, and/or G2.

In some implementations as in FIGS. 10A and 10B, the device includes a deep p-well 1006 is formed a guard ring. A P+ region 1008 is formed with a contact to the region 1008. The P+ region 1008 has a doping profile where the P+ doping is greater than the substrate 1002 and the P-region 1010. In an embodiment, the region 1010 is formed over the substrate 1002 as shown in FIG. 10B. In an embodiment, the region 1010 includes a p-type dopant. The p-type dopant may be greater in concentration than that of the substrate 1002. An n-well 1012 is formed abutting the region 1010. The n-well region may include an n-type dopant at a concentration less than the N+ region 1014.

In an embodiment as shown in FIGS. 10C and 10D, an n-well 1004 is formed on the substrate 1002. The substrate 1002 may be a p-type substrate. In some implementations as in FIGS. 10C and 10D, the device includes a deep p-well 1016 is formed as guard ring. A N+ region 1018 is formed with a contact to the region 1016. The N+ region 1018 has a doping profile where the N+ doping is greater the n-well 1004. A region 1020 is formed in the n-well 1004. The region 1020 may include an n-type dopant at a concentration (e.g., N−) that is less than the n-well 1004 in which it is disposed. A p-well 1022 is formed in the n-well 1004. A P+ region 1024 is formed on the p-well 1022. It is noted that the concentration of p-type dopants in the P+ region 1024 is greater than that that of p-well 1022.

Thus, FIGS. 10A-10D illustrate exemplary structures that may be implemented for one or more of G1, G2 and/or GD for example in the embodiments discussed above in FIGS. 7, 8, 9A-9D.

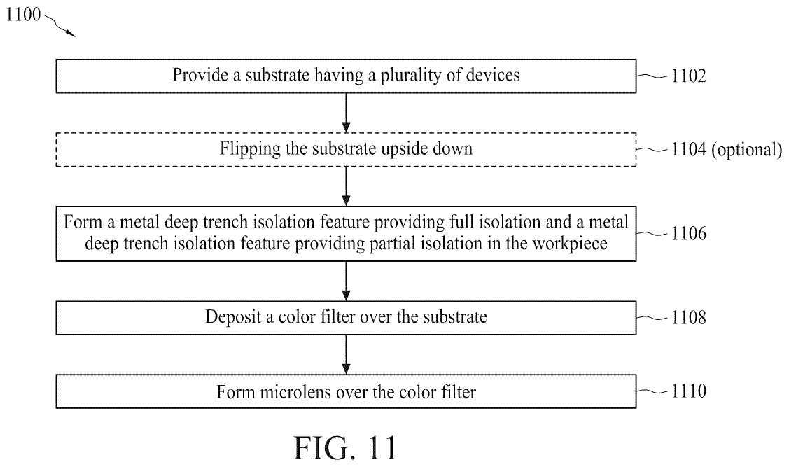

Referring to FIG. 11, illustrated is a flow chart of a method 1100 of forming a CIS according to one or more aspects of the present disclosure. The method 1100 may be implemented to form any one of the devices discussed above alone or in combination. Method 1100 is merely an example and is not intended to limit the present disclosure to what is explicitly illustrated in method 1100. Additional steps may be provided before, during and after the method 1100, and some steps described can be replaced, eliminated, or moved around for additional embodiments of the method. Not all steps are described herein in detail for reasons of simplicity.

At block 1102, a substrate having a plurality of devices formed thereon is provided. In some implementations, the substrate is substantially similar to the substrate 401 discussed above. In an embodiment, the plurality of devices formed thereon may include transistor devices and surrounding dielectric features formed on a first surface of the substrate. For example, the transistor devices may be substantially similar to device 424, discussed above including with reference to FIG. 4. In an embodiment, the surrounding dielectric features may include isolation features such as the isolation features 426 discussed above including with reference to FIG. 4. In an embodiment, a MLI is formed over and connected to the devices disposed on the first surface of the substrate. In further embodiments, gates such as G1, G2, and GD may also be fabricated on the first surface.

At block 1104 of the method 1100, which is optional, the substrate may be flipped such that further processing is performed on its second surface. Block 1104 may be implemented when forming a BSI device. In other embodiments including forming a FSI device, block 1104 may be omitted.

At block 1106 of the method 1100, a metal isolation feature including a metal grid and BDTI feature is formed on a surface (e.g., second surface) of the substrate. The BDTI may include features providing full isolation between photodetectors of a first color filter and a photodetector of a second color filter. The full isolation BDTI feature may be substantially similar to BDTI 408 discussed above including with reference to FIG. 4. The BDTI may also include features providing partial isolation between photodetectors under a color filter. For example, between photodetectors or channels of a DPD or QPD device. The partial isolation BDTI feature may be substantially similar to trench isolation 408′ discussed above including with reference to FIG. 4.

At block 1108 of the method 1100, a color filter may then be disposed over the substrate. In some implementations, the color filter is placed over a second surface of the substrate. For example, when forming a BSI device, the color filter is placed over a second surface of the substrate opposite the first surface of the substrate comprising the plurality of devices of block 1102. The color filters may be substantially similar to the filters 416A, 416B discussed above including with reference to FIG. 4. The color filters may be placed at openings of the grid of the metal isolation feature of block 1106. At block 1110 of the method 1100, a microlens is formed over the color filter layer. The microlens may be substantially similar to the microlens 420 discussed above including with reference to FIG. 4.

Embodiments of the present disclosure provide benefits. For example, the present disclosure provides images sensors that include photodiodes in a sensor substrate. The photodiodes are separated by metal deep trench isolation features that may extend completely through a thickness of the sensor substrate to isolate adjacent pixels. The metal deep trench isolation features may also include trenches that extend partially through a thickness of the substrate to provide for partial isolation between adjacent channels/photodetectors within a pixel, for example between dual photodetectors of a single-color filter pixel in a DPD or between adjacent channels/photodetectors within a QPD. The path for current to flow between the partially isolated channels allows a device to reach FWC at a faster time as the overflow of charge from one channel is provided to an adjacent channel. This leads to faster response time of the device. Also provided are embodiments providing an advantage of using a lateral field charge modulator to enhance high dynamic range (HDR) performance. Also provided are advantages of using various layouts of DPD for a given color pixel that may also provide for faster response time. These features may be used together or separately.

Thus, in some embodiments, the present disclosure provides a semiconductor structure. The semiconductor structure includes a semiconductor device comprising a semiconductor layer and a plurality of isolation trench features disposed in the semiconductor layer. The plurality of isolation trench features includes a first trench extending through an entirety of the semiconductor layer and a second trench extending through a portion of the semiconductor layer and having a terminal end within the semiconductor layer, and a third trench extending through the entirety of the semiconductor layer, wherein the second trench interposes the first trench and the third trench is a cross-sectional view. A color filter is also over the semiconductor layer and a microlens disposed over the color filter.

In an embodiment, the color filter is a single color filter and is vertically over the first trench, the second trench and the third trench. In an embodiment, the second trench extends in a first direction in a top view. In a further implementation, a first photodetector extends between the first trench and the second trench, and a second photodetector extends between the second trench and the third trench. A photocurrent from the first photodetector is operable to transfer to the second photodetector. In some implementations, a third photodetector and a fourth photodetector, wherein the third photodetector and the fourth photodetector are interposed by a fourth trench extending through a portion of the semiconductor layer and having a terminal end within the semiconductor layer and the fourth trench extends in a second direction in a top view. In an embodiment, the plurality of isolation trench features are contiguous with a metal grid disposed over the semiconductor layer and under the microlens. A control gate is formed on a surface of the semiconductor layer, the surface opposing the color filter. And in some implementations, the control gate includes a dual gate. In a further embodiment, a second control gate and a third control gate on the surface of the semiconductor layer and the second and third control gates are single gates. In an embodiment of the structure, the isolation trench features include a dielectric liner layer and a metal layer.

In a broader form on the embodiments of the disclosure, an image sensor includes an array of lens including a first lens and a second lens each disposed over a semiconductor substrate. A first color filter is disposed vertically under the first lens and a second color filter vertically under the second lens. A first deep trench isolation (DTI) feature, a second DTI feature, and a third DTI feature, wherein each of the first DTI feature, the second DTI feature, and the third DTI feature extend from a first surface of the semiconductor substrate to an isolation region on a second surface of the semiconductor substrate. A first dual photodetector (DPD) is vertically under the first lens and the first color filter, and a second DPD is vertically under the second lens and the second color filter. The first DPD is disposed between the first DTI feature and the second DTI feature and the second DPD is disposed between the second DTI feature and the third DTI feature. The first DPD is configured to allow a photoelectric current to flow from a first photodetector of the first DPD to a second photodetector of the first DPD.

In a further embodiment, the first DPD includes a first trench isolation structure extending from the first surface of the semiconductor substrate to a terminal end within the semiconductor substrate and spaced a distance from the second surface of the semiconductor substrate. The first trench isolation structure is disposed between the first photodetector and the second photodetector. In an embodiment, the second DPD is configured to allow a photoelectric current to flow from a third photodetector of the second DPD to a fourth photodetector of the second DPD. And in further implementations, the second DPD includes a second trench isolation structure extending from the first surface of the semiconductor substrate to a terminal end within the semiconductor substrate and spaced another distance from the second surface of the semiconductor substrate. The second trench isolation structure is disposed between the third photodetector and the fourth photodetector. In an embodiment, the first trench isolation structure provides an interface between the first and second photodetectors of the first DPD extending in an x-direction and the second trench isolation structure provides an interface between the third and fourth photodetectors of the second DPD extending in a y-direction. In an embodiment, the first DPD is in a first row of an array of DPDs and the second DPD is in a second row of an array of DPDs. And the first lens and the second lens may provide an aperture, and in a top view a first control gate (G1) and a second control gate (G2) are provided in a first side and an opposing second side of the aperture. In an embodiment, a top view of a third control gate is provided on a third side and a fourth control gate is provided on a fourth side of the aperture, the third control gate and the fourth control gate are dual gate structures, and G1 and G2 are each single gate structures.

In another of the broader embodiments discussed herein, a method of operating an image sensor is discussed. The method includes providing an image sensor having an array of color filters and a plurality of photodetector channels are associated with each color filter of the array of color filters. Incident light is provided to the array of color filters including incident a first color filter of the array of color filters. The incident light is passed through the first color filter to a first photodetector channel and a second photodetector channel. A photoelectric current is provided from the first photodetector channel to the second photodetector channel.

In a further embodiment, providing the image sensor includes providing an array of lens over the array of color filters and the array of lens is offset in an x-direction and y-direction In an embodiment, providing the photoelectric current includes implementing a lateral electrical field charge modulator.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. For example, by implementing different thicknesses for the bit line conductor and word line conductor, one can achieve different resistances for the conductors. However, other techniques to vary the resistances of the metal conductors may also be utilized as well.

What is claimed is:

1. An image sensor, comprising:
an array of lens including a first lens and a second lens each disposed over a first surface of a semiconductor substrate;
a first color filter vertically under the first lens and a second color filter vertically under the second lens;
a metal grid disposed on the first surface of the semiconductor substrate and below the first color filter and the second color filter; and
a first trench isolation feature, a second trench isolation feature, and a third trench isolation feature, wherein the first trench isolation feature extends from the metal grid through the semiconductor substrate from the first surface to a first isolation region formed on a second surface of the semiconductor substrate, and wherein the third trench isolation feature extends from the metal grid through the semiconductor substrate from the first surface to a third isolation region formed on the second surface, and wherein the second trench isolation feature extends from the metal grid through the semiconductor substrate from the first surface to a terminal end of the second trench isolation feature within the semiconductor substrate; and
wherein in a cross-sectional view, the first trench isolation feature extends below a first end of the first color filter and the third trench isolation feature extends below a second end of the first color filter, the second trench isolation feature extends below a center region of the first color filter.

2. The image sensor of claim 1, wherein a second isolation region is disposed on the second surface below the second trench isolation feature, a semiconductor material of the semiconductor substrate extending between the second trench isolation feature and the second isolation region.

3. The image sensor of claim 2, wherein a gate structure interposes the first isolation region and the second isolation region.

4. The image sensor of claim 3, wherein another gate structure interposes the second isolation region and the third isolation region.

5. The image sensor of claim 4, wherein the gate structure is a first control gate and the another gate structure is another control gate.

6. The image sensor of claim 4, wherein the gate structure and the another gate structure turn-on based on light exposure.

7. The image sensor of claim 3, wherein the gate structure is adjacent to the first trench isolation feature.

8. The image sensor of claim 7, wherein another gate structure is adjacent the third trench isolation feature.

9. A semiconductor device, comprising:
a semiconductor layer having a first surface and a second surface opposing the first surface;
a plurality of isolation trench features disposed in the semiconductor layer and extending from the first surface, wherein the plurality of isolation trench features includes a first trench extending through an entirety of the semiconductor layer from the first surface to the second surface and a second trench extending from the first surface through a portion of the semiconductor layer and having a terminal end within the semiconductor layer, and a third trench extending through the entirety of the semiconductor layer from the first surface to the second surface, wherein the second trench interposes the first trench and the third trench is a cross-sectional view;
a color filter over the semiconductor layer;
a microlens disposed over the color filter; and
a first gate and a second gate disposed between the first trench and the third trench in the cross-sectional view.

10. The semiconductor device of claim 9, wherein the first gate and the second gate are disposed between the first trench and the second trench in the cross-sectional view.

11. The semiconductor device of claim 9, wherein the first gate includes a P+ region formed within a p-well region and the second gate includes another P+ region formed within another p-well region.

12. The semiconductor device of claim 11, wherein an n-well region in the semiconductor layer is disposed between the p-well region and the another p-well region.

13. The semiconductor device of claim 12, wherein the n-well region is a U-shape region and a p-type region is formed in the semiconductor layer within an opening of the U-shape region in the cross-sectional view.

14. A method of fabricating an image sensor, comprising:
providing a substrate having a transistor device;
forming a multi-layer interconnect connected to the transistor device;
fabricating a metal isolation feature including a metal grid and a plurality of trench isolation features extending from the metal grid, wherein the fabricating the metal isolation feature includes:
forming a first trench isolation feature of the plurality of trench isolation features extending a first depth; and
forming a second trench isolation feature of the plurality of trench isolation extending to a second depth, wherein the first depth is less than the second depth;
depositing a color filter over the metal isolation feature; and
forming a microlens over the color filter.

15. The method of claim 14, further comprising:
flipping the substrate such that fabricating the metal isolation feature occurs on a second surface opposite a surface providing the transistor device.

16. The method of claim 14, wherein a first color of the color filter is formed over each of the first trench isolation feature and the second trench isolation feature.

17. The method of claim 14, wherein fabricating the metal isolation feature includes:
etching the substrate to form a plurality of trenches;
filling the plurality of trenches with dielectric material;
depositing metal over the substrate and the filled plurality of trenches; and
patterning the metal to form the metal grid.

18. The method of claim 17, wherein the etching the substrate to form the plurality of trenches etching a first plurality of trenches extending to the first depth and a second plurality of trenches extending to the second depth.

19. The method of claim 17, wherein filling the plurality of trenches with dielectric material includes depositing a dielectric liner layer.

20. The method of claim 14, wherein a shallow trench isolation feature is adjacent to the transistor device and forming the second trench isolation feature includes extending a trench through the substrate to the shallow trench isolation feature.
